(19) United States
(12) Patent Application Publication
(10) Pub. No.: US 2006/0169207 A1
(43) Pub. Date: Aug. 3, 2006

(54) Semiconductor manufacturing apparatus capable of preventing adhesion of particles

(76) Inventors: Hiroyuki Kobayashi, Kodaira (JP); Kenetsu Yokogawa, Tsurugashima (JP); Masaru Izawa, Hino (JP); Kenji Maeda, Kudamatsu (JP); Tomoyuki Tamura, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/068,780

(22) Filed: Mar. 2, 2005

(30) Foreign Application Priority Data
Feb. 2, 2005 (JP) 2005-026892

(51) Int. Cl. G01N 5/02; H01L 21/44; C23C 16/00

(52) U.S. Cl. 118/715; 73/73; 438/680

(57) ABSTRACT

A semiconductor manufacturing apparatus includes a vacuum processing chamber and a transportation chamber each including a gas supply unit and a gas exhaust unit, a sample placing electrode for placing a sample thereon and holding the sample in the processing chamber, a gate valve for opening/closing a passage between the processing chamber and the transportation chamber, a transportation device including a transportation arm disposed in the transportation chamber and a sample holding portion disposed at a tip of the arm to hold the sample on the sample holding portion, transport the sample from the transportation chamber to the processing chamber, and transport the processed sample from the processing chamber to the transportation chamber, and a gas blowing unit for blowing gas against the sample so as to be interlocked with a transportation position of the sample being transported to prevent adhesion of floating particles to a surface of the sample.

### BACKGROUND OF THE INVENTION

The present invention relates to a semiconductor manufacturing apparatus. In particular, the present invention relates to a semiconductor manufacturing apparatus capable of suppressing the quantity of particles adhering to samples such as wafers.

In manufacturing processes of semiconductor devices such as DRAMs and microprocessors, plasma etching apparatuses and plasma CVD apparatuses are widely used. For improving the yield in manufacture of semiconductor devices, it is important to prevent particles from adhering to samples when conducting predetermined processing on the samples such as wafers or when transporting the samples.

For example, if etching is conducted in a state in which a particle having a diameter of 100 nm adheres right above wiring in a semiconductor device having a wiring width of 50 nm, etching processing is locally hampered in the portion where the particle adheres, resulting in a defect such as an open circuit.

As for non-charged particles each having a size of approximately several tens nm to several μm, a motion riding on the gas flow becomes dominant when the gas pressure is more than several pascals. As described in, for example, JP-A-2000-173935, it is possible to prevent particles from adhering to a sample by keeping a state in which clean gas is blown against the sample while plasma processing is not being conducted.

Coulomb force becomes dominant on the motion of electric-charged-particles. As described in, for example, JP-A-5-47712, it becomes possible to prevent electric-charged-particles from adhering to the sample by controlling the electric field distribution in a processing chamber.

### SUMMARY OF THE INVENTION

As described in JP-A-2000-173935 or JP-A-5-47712, the technique of preventing particles from adhering to the sample is a technique intended for the state in which the sample is at a standstill. It is not a technique for preventing particles from adhering to the sample that is being transported.

As for the cause of adhesion of particles to the sample occurring during the transportation, the fact that a measure against particles with the motion of the sample during transportation taken into consideration is not taken heretofore, the fact that the measure for keeping the inside of the transportation chamber clean is insufficient, and the fact that the gas flow abruptly changes and the particles are flung up can be mentioned. The present invention has been achieved in order to solve the problems. An object of the present invention is to provide a semiconductor manufacturing apparatus capable of suppressing the quantity of the particles adhering to the sample.

In order to achieve the object, a semiconductor manufacturing apparatus according to one aspect of the invention includes a vacuum processing chamber including gas supply means and gas exhaust means, a sample placing electrode for placing a sample thereon and holding the sample in the vacuum processing chamber, a transportation chamber including gas supply means and gas exhaust means, a gate valve for opening and closing a passage used for communication between the vacuum processing chamber and the transportation chamber, a transportation device including a transportation arm disposed in the transportation chamber and a sample holding portion disposed at a tip of the transportation arm, the transportation device holding the sample on the sample holding portion, transporting the sample from the transportation chamber to the vacuum processing chamber, and transporting the processed sample from the vacuum processing chamber to the transportation chamber, and gas blowing means for blowing gas against the sample so as to be interlocked with a transportation position of the sample which is being transported and thereby preventing adhesion of floating particles to a surface of the sample.

Owing to the configuration heretofore described, the present invention can suppress the quantity of particles adhering to the sample.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram showing a semiconductor manufacturing apparatus according to a first embodiment of the present invention;

FIGS. 2A and 2B are diagrams showing details of a transportation robot shown in FIG. 1;

FIG. 3 is a diagram showing an action of a gas injection nozzle installed in a processing chamber;

FIG. 4 is a diagram showing a shape of a slit shown in FIG. 1;

FIG. 5 is a diagram showing a gas flow in a state in which a slit is attached around a placing electrode;

FIG. 6 is a diagram showing details around a gate valve;

FIGS. 7A, 7B and 7C are diagrams showing a processing sequence of a semiconductor manufacturing apparatus shown in FIG. 1;

FIGS. 8A and 8B are diagrams showing a second embodiment of the present invention;

FIGS. 9A and 9B are diagrams showing a third embodiment of the present invention;

FIGS. 10A and 10B are diagrams showing a fourth embodiment of the present invention;

FIG. 11 is a diagram showing a fifth embodiment of the present invention; and

FIG. 12 is a diagram showing a sixth embodiment of the present invention.

### DETAILED DESCRIPTION OF THE EMBODIMENTS

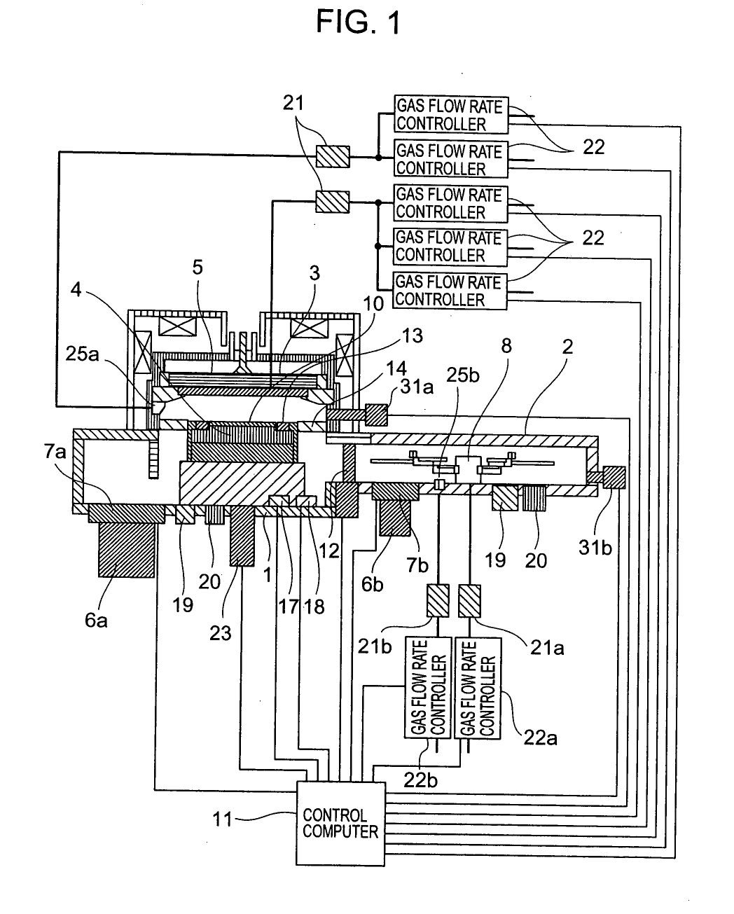

Hereafter, embodiments will be described with reference to accompanying drawings. FIG. 1 is a diagram showing a semiconductor manufacturing apparatus according to a first embodiment of the present invention. In the example shown in FIG. 1, a parallel plate UHF-ECR (Electron Cyclotron Resonance) plasma etching apparatus is used as a semiconductor manufacturing apparatus.

As shown in FIG. 1, the etching apparatus includes a processing chamber 1, a transportation chamber 2, and a load-lock chamber (not illustrated). A gate valve 12 is installed between the processing chamber 1 and the transportation chamber 2. In an upper part of the processing chamber 1, a plane antenna 3 for emitting an electromagnetic wave is disposed in parallel to an electrode 4 for placing a sample 10 thereon.

A discharge power supply (not illustrated) for generating plasma and a bias power supply (not illustrated) for applying a bias to the antenna are connected to the antenna 3. A bias power supply (not illustrated) for accelerating ions incident on the sample is connected to the electrode 4. The electrode 4 is movable upward and downward. A slit 14 is attached around the periphery of the electrode 4. A shower plate 5 is disposed under the antenna 3. Processing gas is supplied to the inside of the processing chamber via gas holes formed through the shower plate.

A gas injection nozzle 25a is installed on the opposite side of the transportation chamber in the processing chamber 1 to inject gas toward the sample without using the gas holes formed through the shower plate. A flow rate of gas supplied to the inside of the processing chamber can be adjusted by gas flow rate controllers 22. Filters 21 are disposed between the gas flow rate controllers 22 and the gas injection nozzle 25a and between the gas flow rate controllers 22 and the shower plate 5 in order to prevent particles generated in a gas pipe and the gas flow rate controllers from intruding into the processing chamber.

A turbo-molecular pump 6a for decreasing the pressure in the processing chamber is attached to the processing chamber 1. A butterfly valve 7a is attached to top of the turbo-molecular pump 6a to control the pressure in the processing chamber.

A turbo-molecular pump 6b is attached to the transportation chamber 2 in order to decrease the pressure in the transportation chamber. A butterfly valve 7b is attached to top of the turbo-molecular pump 6b to adjust the pressure in the transportation chamber 2. A gas supply nozzle 25b for supplying gas is installed in the transportation chamber 2. A flow rate of gas supplied from the gas supply nozzle 25b is adjusted by a gas flow rate controller 22b. A filter 21b is disposed between the gas flow rate controller 22b and the gas supply nozzle 25b in order to prevent particles generated in a gas pipe and the gas flow rate controllers from intruding into the processing chamber.

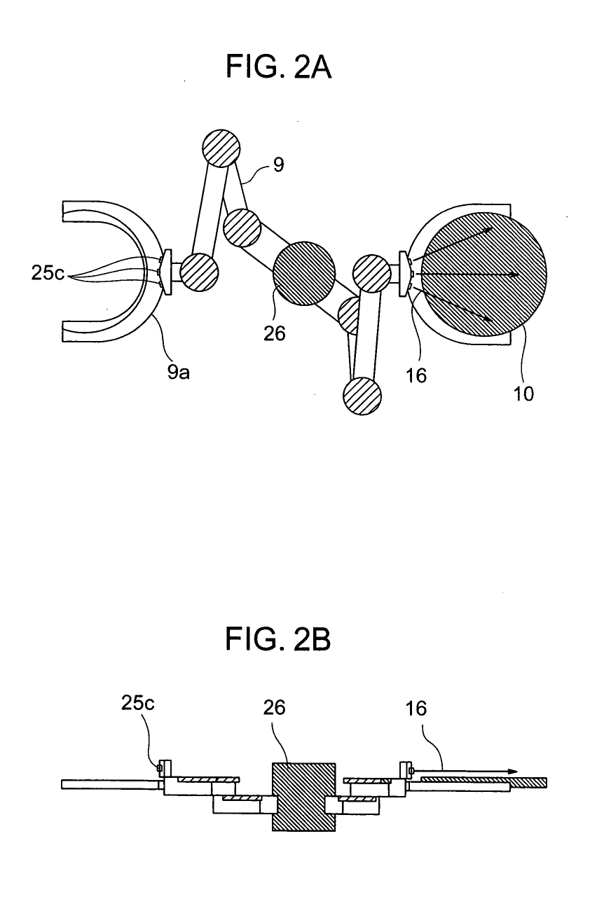

FIGS. 2A and 2B are diagrams showing details of a transportation robot 8 shown in FIG. 1. As shown in FIG. 1, the transportation robot 8 for transporting the sample 10 is attached in the transportation chamber 2. The transportation robot 8 includes two sets of transportation means, each set including a transportation arm 9 and a sample holding portion 9a disposed at the tip of the transportation arm.

A gas injection nozzle 25c is attached to the sample holding portion 9a of the transportation arm. Gas is injected in a direction nearly parallel to the sample placed on the sample holding portion 9a. Since the gas injection nozzle 25c moves so as to be interlocked with the motion of the sample holding portion, particles coming flying to the sample during transportation of the sample are blown off by gas injected from the gas injection nozzle 25c to prevent the particles from adhering to the sample.

As gas (clean gas) supplied from the gas injection nozzle 25c, for example, nitrogen gas of a low cost or rare gas such as argon can be used. The flow rate of gas supplied from the gas injection nozzle 25c is adjusted by a gas flow rate controller 22a. In addition, it is possible to prevent particles generated in a gas pipe arrangement and the gas flow rate controller 22a from flowing in the processing chamber by disposing a filter 21a between the gas exhaust nozzle 25c and the gas flow rate controller 22a.

All transportation robots and transportation arms are grounded to prevent a change in the electric field distribution in the transportation chamber from occurring even when the transportation arm has moved. As a result, whirling up of electric-charged-particles can be suppressed.

In FIG. 1, vacuum gauges 31a and 31b are attached to the processing chamber 1 and the transportation chamber 2, respectively. When opening the gate valve 12, gas such as Ar or nitrogen is supplied to the processing chamber 1 and the transportation chamber 2. At this time, a control computer 11 conducts pressure control so as to provide the transportation chamber 2 with a predetermined positive pressure as compared with the processing chamber 1 by adjusting the exhaust rates of the transportation chamber 2 and the processing chamber 1. As a result, gas flows from the transportation chamber 2 toward the processing chamber 1 when the gate valve is opened. Therefore, neither particles in the processing chamber 1 nor corrosion gas or deposition gas remaining in the processing chamber 1 flows into the transportation chamber 2.

It is desirable that the pressure of the processing chamber and the transportation chamber is at least several Pa. Furthermore, it is desirable that a difference pressure between the transportation chamber and the processing chamber is at least several Pa in order to form a gas flow having a sufficient flow rate from the transportation chamber to the processing chamber. In addition, it is desirable that a difference pressure between the processing chamber and the transportation chamber does not exceed several tens Pa in order to suppress the whirling up of particles caused by a gas flow. Unless the transportation chamber has a positive pressure in a predetermined pressure range as compared with the processing chamber, interlocking should be executed by the control computer 11 so as to prevent the gate valve from being opened.

A concentration sensor 17 for the corrosion gas and a concentration sensor 18 for deposition gas are disposed in the processing chamber 1. The concentration sensors 17 and 18 are connected to the control computer 11. Unless each of concentration of the corrosion gas in the processing chamber 1 and concentration of the deposition gas in the processing chamber 1 is equal to or less than a predetermined concentration, interlocking should be executed by the control computer 11 so as to prevent the gate valve from being opened.

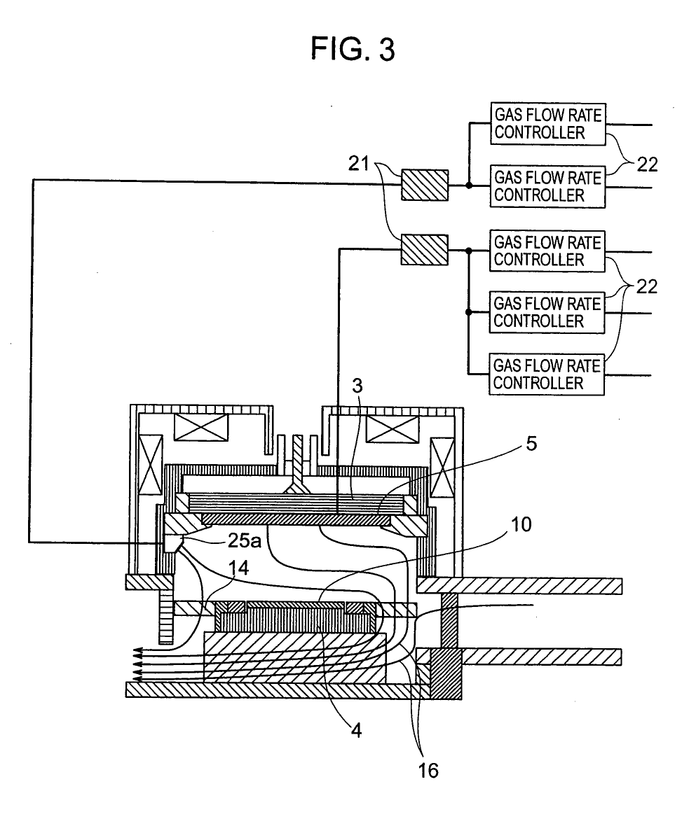

FIG. 3 is a diagram showing an action of the gas injection nozzle 25a installed in the processing chamber 1. FIG. 3 shows a state in which the electrode 4 is lowered downward and the gate valve 12 is opened.

If in this state gas is exhausted from only the shower plate 5, a part of gas coming flying from the transportation chamber 2 arrives at top of the sample. Therefore, particles coming flying from the transportation chamber 2 might adhere to the sample placed on the placing electrode 4.

On the other hand, it is possible to control gas flow to prevent gas flowing from the transportation chamber 2 into the processing chamber 1 from flowing to the top of the sample 10 placed on the electrode 4 as shown in FIG. 3A, by supplying gas from the gas injection nozzle 25a disposed across the processing chamber 1 from the transportation chamber 2. As a result, it is possible to prevent particles coming flying from the transportation chamber 2 from adhering to the sample placed on the electrode 4.

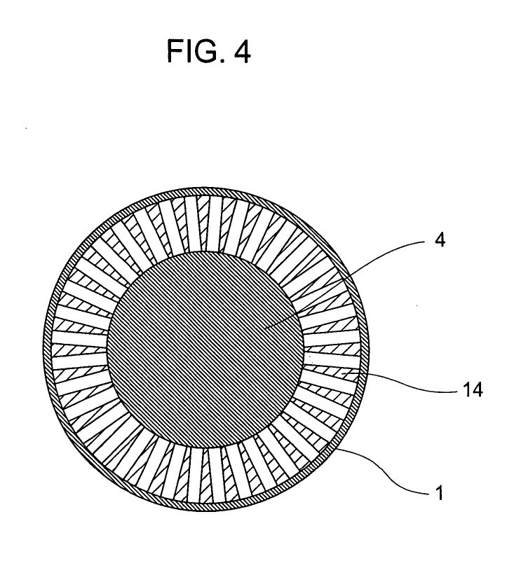

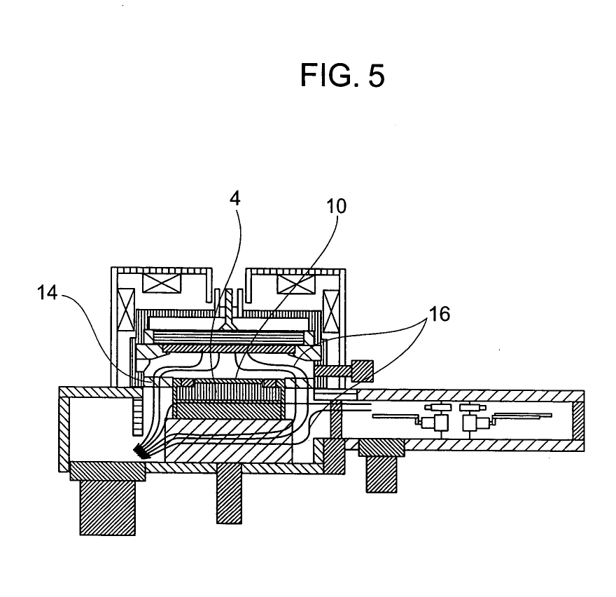

FIG. 4 is a diagram showing a shape of the slit 14 shown in FIG. 1. FIG. 5 is a diagram showing gas flow in the state in which the slit 14 is attached around the placing electrode 4.

As shown in FIG. 4, the slit 14 includes a plurality of radial fins and a plurality of radial slits formed between the fins.

The slit 14 is attached around the periphery of the electrode 4 as shown in FIG. 5. The slit 14 moves upward and downward simultaneously with the electrode 4. When the electrode 4 is raised to an upper processing position, the slit 14 is positioned higher than a transportation port which connects the processing chamber 1 and the transportation chamber 2 as shown in FIG. 1. When opening the gate valve 12, gas is supplied from the shower plate 5 and the electrode is already raised upward.

The position control of the electrode 4 at the time when opening the gate valve 12 and the role of the slit 14 attached around the periphery of the electrode 4 will now be described. In FIG. 5, gas flows at this time are indicated by arrow lines 16. Owing to the flow of gas supplied from the shower plate 5, it is thus possible to prevent particles flowing from the transportation chamber 2 into the processing chamber 1 or particles whirled up in a lower part of the processing chamber 1 from coming flying to the top of the sample placed on the placing electrode 4. Furthermore, since the flow rate of gas supplied from the shower plate 5 becomes fast near the slit 14, it becomes possible to further suppress the coming flying of particles to the sample placed on the electrode 4 by installing the slit 14.

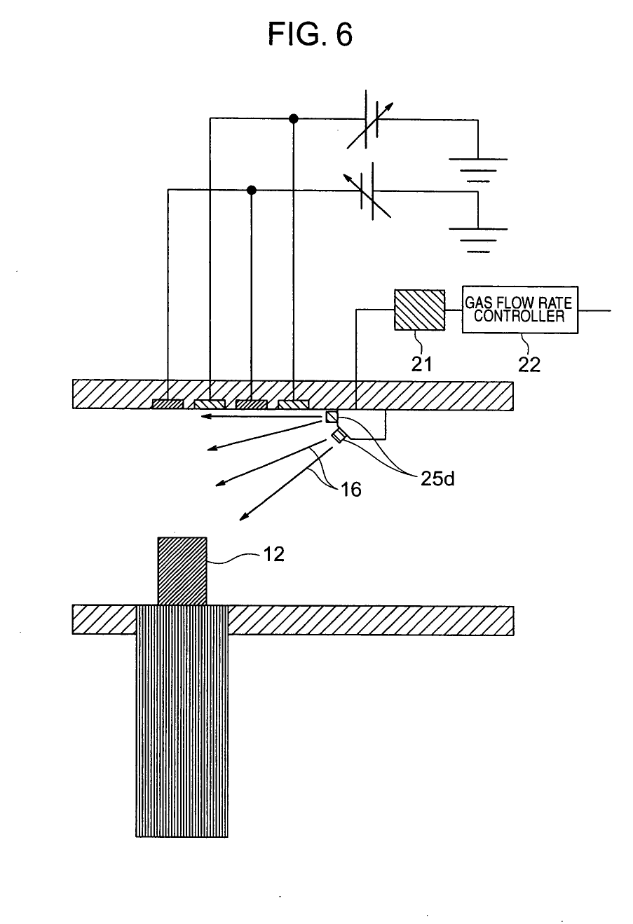

FIG. 6 is a diagram showing details around the gate valve 12. Since the gate valve is driven upward or downward at the time of opening and closing, the gate valve is apt to generate particles. Therefore, gas injection nozzles 25d for blowing gas against the vicinity of the gate valve 12 are installed. As a result, it is possible to blow off particles that are present near the gate valve before transporting the sample. In addition, in order to attract electric-charged-particles floating near the gate valve by means of Coulomb force, electrodes for locally applying positive and negative voltages to the vicinity of the gate valve are provided near the gate valve. As a result, it is possible to suppress adhesion of particles to the sample caused when the sample passes through the vicinity of the gate valve.

As shown in FIG. 1, an ion source 19 and an electric precipitator 20 are attached to each of the transportation chamber 2 and the processing chamber 1. It is possible to ionize particles whirled up when opening or closing the gate valve by using the ion source 19 and remove the particles by using the electric precipitator 20. Since minus ions are better in generation efficiency than plus ions, it is desirable to use an apparatus for generating minus ions as the ion source.

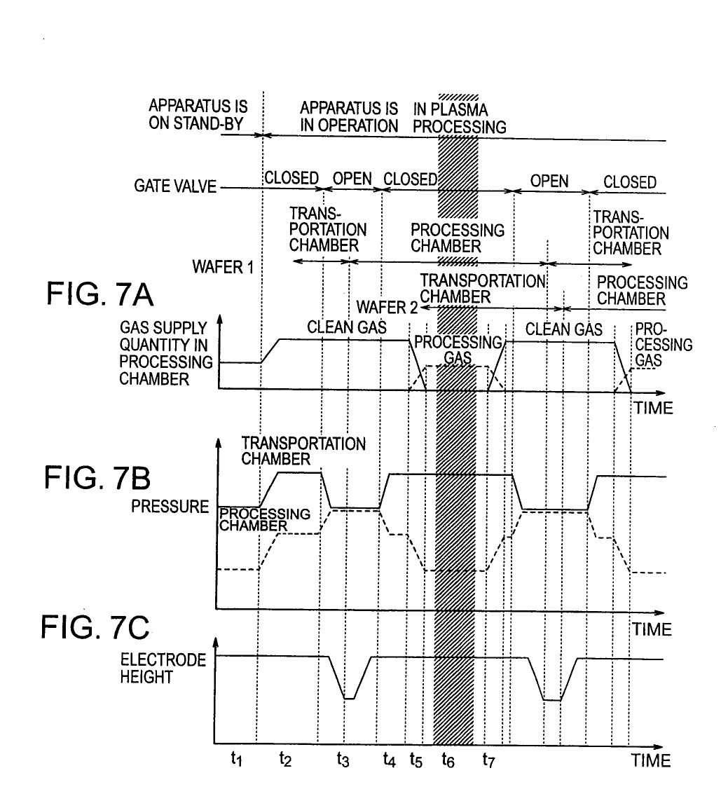

FIGS. 7A, 7B and 7C are diagrams showing a processing sequence of a semiconductor manufacturing apparatus shown in FIG. 1. If the semiconductor manufacturing apparatus is in the stand-by state, Ar gas is let flow at a flow rate of, for example, 500 cc/min in the processing chamber and 200 cc/min in the transportation chamber. Ar gas is supplied from the shower plate 5 and the gas injection nozzle 25a to the inside of the processing chamber, and supplied from the gas injection nozzle 25c attached to the transportation arm to the inside of the transportation chamber 2 (t1). Before starting the sample transportation, the flow rates of Ar gas supplied to the processing chamber 1 and the transportation chamber 2 are increased to, for example, 1,000 cc/min and 500 cc/min, respectively. The exhaust rates are adjusted so as to make pressures of the processing chamber and the transportation chamber equal to, for example, 10 Pa and 15 Pa, respectively (t2). Subsequently, the sample is transported from the load-lock chamber to the transportation chamber. Subsequently, the gate valve is opened, and then the electrode 4 is lowered to the transportation position. The sample is placed on the electrode 4, and then the electrode 4 is raised upward (t3). Thereafter, the gate valve is closed (t4). Subsequently, the supply quantity of processing gas is gradually increased while the flow rate of Ar gas is being gradually decreased, in order to conduct predetermined processing by using plasma. The processing gas is supplied from the shower plate (t5). After predetermined processing (t6) is finished, the supply quantity of Ar gas is gradually increased while the supply quantity of the processing gas is being gradually decreased. The reason why the supply quantity of gas is gradually increased or decreased is that whirling up of particles caused by an abrupt change in the gas flow should be suppressed (t5, t7).

When outward transportation of the sample is finished and the apparatus is brought into the stand-by state, gas remains to be let flow in the processing chamber and the transportation chamber respectively at flow rates of, for example, 1,000 cc/min and 500 cc/min until a predetermined time elapses since the outward transportation of the sample. Thereafter, the apparatus is on stand-by in the state in which the gas flow rates are reduced to, for example, 500 cc/min and 200 cc/min, respectively, in order to reduce the cost.

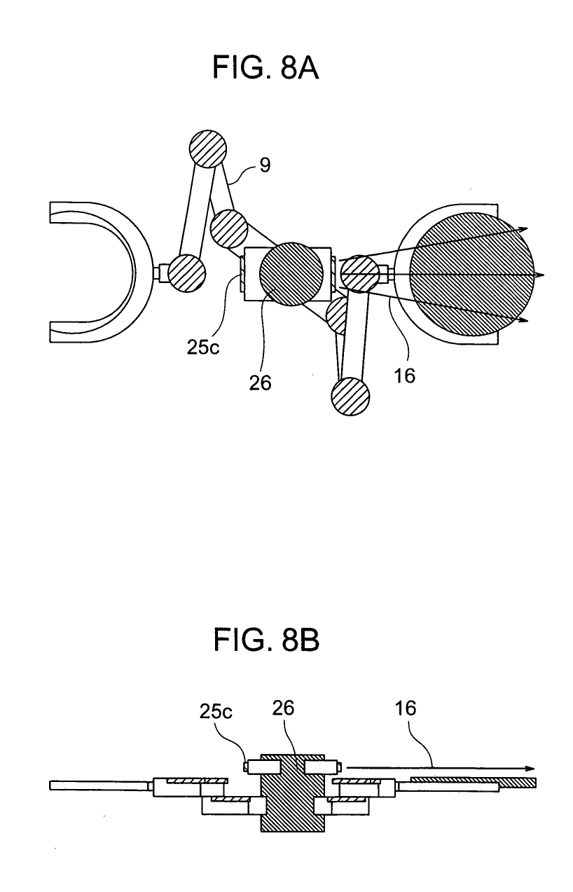

FIGS. 8A and 8B are diagrams showing a second embodiment of the present invention. A configuration other than the transportation robot 8 is the same as that shown in FIG. 1, and consequently its description will be omitted. FIG. 8A is a top view of the transportation robot. FIG. 8B is a side view of the transportation robot. As shown in FIGS. 8A and 8B, the gas injection nozzle 25c for injection gas in a direction nearly parallel to the sample is attached to a central axis 26 of the transportation robot. The gas injection nozzle 25c is rotated so as to be interlocked with the rotation operation of the transportation robot. In the transportation operation of the sample, therefore, it is possible to always blow gas against the sample. In the example shown in FIGS. 8A and 8B, the flow rate of gas blown against the sample when the arm 9 is extended becomes lower than that in the first embodiment shown in FIG. 1. Since it is not necessary to interlock the gas pipe arrangement with the extension and contraction of the arm, however, its structure becomes simple.

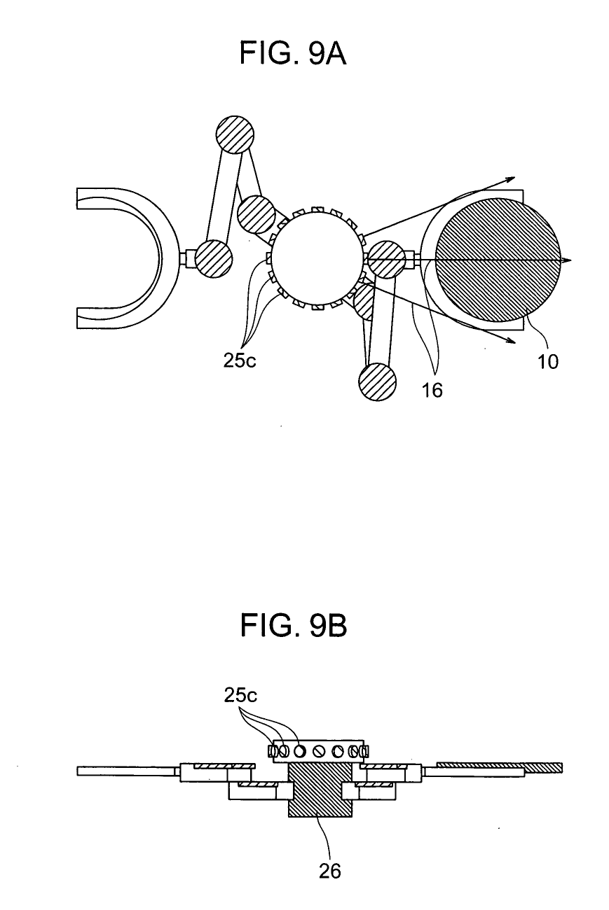

FIGS. 9A and 9B are diagrams showing a third embodiment of the present invention. A configuration other than the transportation robot 8 is the same as that shown in FIG. 1, and consequently its description will be omitted. FIG. 9A is a top view of the transportation robot. FIG. 9B is a side view of the transportation robot. In this example, a plurality of gas injection nozzles 25c for injection gas in a direction nearly parallel to the sample 10 are installed in a circumferential direction around a central axis 26 of the transportation robot as shown in FIGS. 9A and 9B. Gas injection is controlled every gas injection nozzle so as to inject gas from only an injection nozzle located in a position in which gas can be blown against the sample, among the gas injection nozzles. As a result, it is possible to blow gas against the sample nearly in the parallel direction no matter where in the transportation chamber the sample is located. In the case of this example, there is a merit that the gas injection nozzle can be fixed unlike the example shown in FIGS. 8A and 8B.

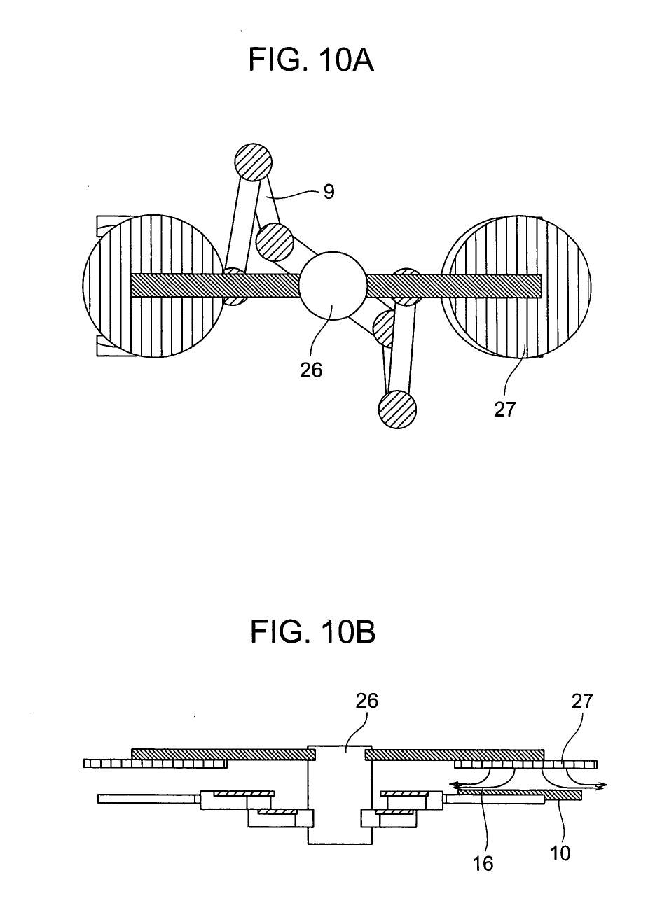

FIGS. 10A and 10B are diagrams showing a fourth embodiment of the present invention. A configuration other than the transportation robot 8 is the same as that shown in FIG. 1, and consequently its description will be omitted. FIG. 10A is a top view of the transportation robot. FIG. 10B is a side view of the transportation robot.

In this example, a shower head 27 which is rotated so as to be interlocked with the central axis of the transportation robot is installed over the transportation arm 9. A plurality of gas holes are formed on the shower head 27 to supply gas toward the sample placed on the sample holding portion 9a of the transportation arm 9 from above. As a result, it is possible to suppress adhesion of particles floating in the transportation chamber to the sample. In this example, the transportation system becomes large-sized because of the installation of the shower head 27. As compared with the foregoing embodiments, however, the effect of suppressing adhesion of particles to the sample is high.

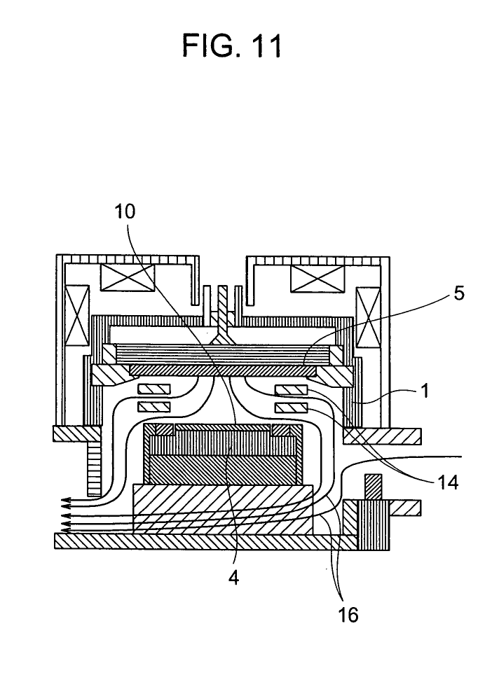

FIG. 11 is a diagram showing a fifth embodiment of the present invention. Parts that are the same as those shown in FIG. 1 will be omitted in description. In this example, a plurality of doughnut-shaped disks 14 each having an inside diameter larger than the sample are installed so as to be in proximity to each other between the peripheral portion of the placing electrode 4 and the top of the processing chamber 1. As a result, a plurality of slits are formed between a plurality of disks, between a disk located on the highest side among the disks and the top of the processing chamber, and between a disk located on the lowest side and the placing electrode. In the same way as the slit 14 shown in FIG. 5, the slits can suppress adhesion of particles flowing in from the transportation chamber and particles whirled up in the processing chamber to the sample placed on the placing electrode.

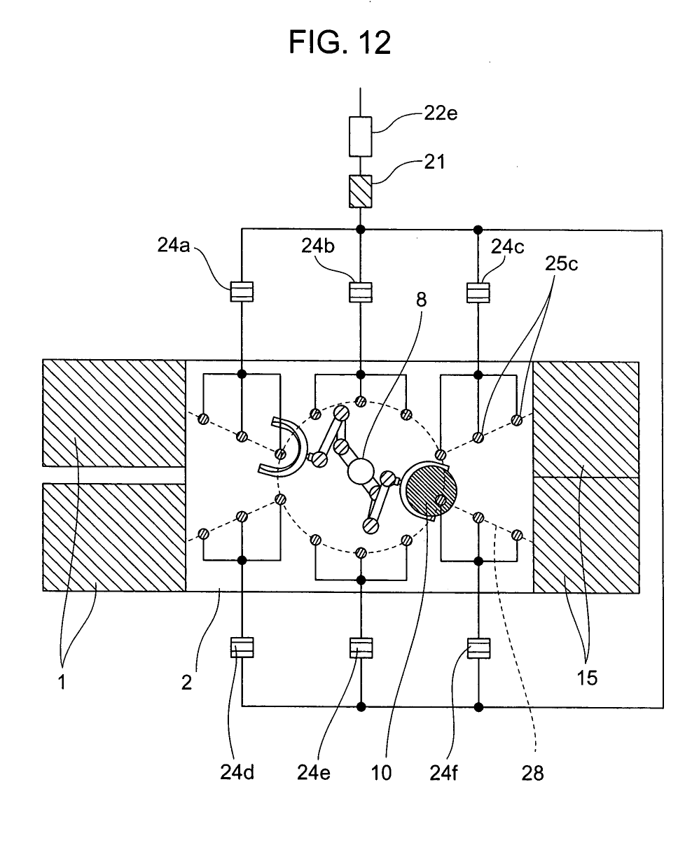

FIG. 12 is a diagram showing a sixth embodiment of the present invention. FIG. 12 is a schematic top view of a plasma etching apparatus. As shown in FIG. 12, the etching apparatus includes a processing chamber 1, a transportation chamber 2, and a load-lock chamber 15.

In an upper part of the transportation chamber 2, a plurality of gas injection nozzles 25c are installed along a locus 28 of sample transportation at the time of transportation operation. In a downstream of a gas flow rate controller 22e, a gas arrangement is branched into a plurality of systems, and valves 24 (24a to 24f) are disposed in the branches, respectively. The gas exhaust nozzles 25c are connected to the downstream side of each valve. It is possible to always exhaust gas from above the sample in transportation by controlling the opening and closing of the valves 24 (24a to 24f) so as to be interlocked with the transportation operation of the sample. As a result, adhesion of particles to the sample in the transportation chamber can be suppressed.

Heretofore, examples of using a plasma etching apparatus as the semiconductor manufacturing apparatus have been described. However, the present invention can be applied widely to other semiconductor manufacturing apparatuses such as plasma CVD apparatuses as well.

According to the embodiments, the gas flow in the transportation chamber and the processing chamber is controlled so as to be interlocked with the sample transportation operation as heretofore described. As a result, the number of particles adhering to the sample during the transportation can be reduced, and the yield can be improved.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor manufacturing apparatus comprising:
a vacuum processing chamber comprising gas supply means and gas exhaust means;
a sample placing electrode for,placing a sample thereon and holding the sample in said vacuum processing chamber;
a transportation chamber comprising gas supply means and gas exhaust means;
a gate valve for opening and closing a passage used for communication between said vacuum processing chamber and said transportation chamber;
a transportation device comprising a transportation arm disposed in said transportation chamber and a sample holding portion disposed at a tip of said transportation arm, said transportation device holding the sample on said sample holding portion, transporting the sample from said transportation chamber to said vacuum processing chamber, and transporting the processed sample from said vacuum processing chamber to said transportation chamber; and
gas blowing means for blowing gas against the sample so as to be interlocked with a transportation position of the sample which is being transported and thereby preventing adhesion of floating particles to a surface of the sample.

2. A semiconductor manufacturing apparatus according to claim 1, wherein said transportation device comprises gas blowing means in which a gas blowing direction can be variably controlled.

3. A semiconductor manufacturing apparatus according to claim 1, wherein said gas blowing means comprises a plurality of gas injection nozzles disposed along a transportation path of the sample to each injection gas so as to be interlocked with a transportation position of the sample.

4. A semiconductor manufacturing apparatus according to claim 1, wherein said gas blowing means blows gas against said gate valve when opening and closing said gate valve.

5. A semiconductor manufacturing apparatus according to claim 1, wherein each of said transportation chamber and said vacuum chamber comprises a pressure gauge for measuring an internal pressure, and an interlock for permitting opening said gate valve only when a pressure in said transportation chamber is greater than a pressure in said vacuum processing chamber by several to several tens Pa (pascal).

6. A semiconductor manufacturing apparatus according to claim 1, comprising a slit for separating a space on said sample placing electrode from a space around said sample placing electrode in an ordinary position in which said sample placing electrode has been raised, said slit being fixed to said vacuum processing chamber side.

7. A semiconductor manufacturing apparatus according to claim 1, comprising a slit disposed over said passage to separate a space on said sample placing electrode from a space around said sample placing electrode in an ordinary position in which said sample placing electrode has been raised, said slit being fixed to said sample placing electrode side.

8. A semiconductor manufacturing apparatus according to claim 1, wherein said transportation chamber comprises an ion source for emitting ions and an absorption electrode for absorbing ionized particles.

9. A semiconductor manufacturing apparatus according to claim 1, wherein said vacuum processing chamber comprises an ion source for emitting ions and an absorption electrode for absorbing ionized particles.

10. A semiconductor manufacturing apparatus according to claim 1, wherein said vacuum processing chamber comprises a measuring instrument for measuring concentration of internal corrosive gas or deposition gas, and an interlock for permitting opening said gate valve only when the measured concentration is equal to a predetermined value or less.

11. A semiconductor manufacturing apparatus according to claim 1, wherein said transportation chamber and said transportation arm are grounded.

12. A semiconductor manufacturing apparatus according to claim 1, wherein said gas blowing means supplies gas to said transportation chamber and said vacuum processing chamber until a predetermined time elapses after the processed sample is transported from said vacuum processing chamber to said transportation chamber.

13. A semiconductor manufacturing apparatus according to claim 1, wherein said gas blowing means reduces a flow rate of gas supplied to said transportation chamber and said vacuum processing chamber after the predetermined time has elapsed.

14. A semiconductor manufacturing apparatus comprising:
a vacuum processing chamber comprising gas supply means and gas exhaust means;
a sample placing electrode for placing a sample thereon and holding the sample in said vacuum processing chamber;
a transportation chamber comprising gas supply means and gas exhaust means;
a gate valve for opening and closing a passage used for communication between said vacuum processing chamber and said transportation chamber; and
a transportation device comprising a transportation arm disposed in said transportation chamber and a sample holding portion disposed at a tip of said transportation arm, said transportation device holding the sample on said sample holding portion, transporting the sample from said transportation chamber to said vacuum processing chamber, and transporting the processed sample from said vacuum processing chamber to said transportation chamber,
wherein scattering of particles toward the sample is suppressed by controlling a gas flow in said vacuum processing chamber and said transportation chamber so as to be interlocked with transportation operation of the sample.

15. A semiconductor manufacturing apparatus according to claim 14, wherein said vacuum processing chamber comprises a gas exhaust nozzle for injecting gas onto the sample nearly on a side opposite to a transportation port which connects said transportation chamber to said processing chamber, besides a gas exhaust nozzle for supplying processing gas.

16. A semiconductor manufacturing apparatus according to claim 14, wherein said sample placing electrode is raised when opening and closing said gate valve.
